(19) United States
(12) Patent Application Publication
(10) Pub. No.: US 2021/0104477 A1
(43) Pub. Date: Apr. 8, 2021

(54) PAD STRUCTURE

(71) Applicant: MACRONIX INTERNATIONAL CO., LTD., Hsinchu (TW)

(72) Inventors: Chih-Ching Eric SHIH, Taoyuan City (TW); Hung-Chi CHEN, Zhubei City (TW); Li-Kuang KUO, Hsinchu City (TW); Wen-Pin LU, Zhubei City (TW)

(21) Appl. No.: 16/592,940

(22) Filed: Oct. 4, 2019

(51) Int. Cl. H01L 23/00; H01L 23/485; H01L 23/528; H01L 23/31

(52) U.S. Cl. CPC H01L 24/05; H01L 23/3114; H01L 23/5283; H01L 23/485

(57) ABSTRACT

A pad structure includes a conductive layer, a pad layer, a protective layer and a dielectric layer. The conductive layer is located above the substrate. The protective layer covers the pad layer and has an opening to expose a portion of the pad layer. The dielectric layer is formed between the conductive layer and the pad layer and between the conductive layer and the pad layer. The conductive layer includes a number of effective blocks, and a proportion of a block area of a block of the effective blocks to a total block area of the effective blocks ranges between 40%-50%. The block has at least one hollow portion, wherein the hollow portion has a total hollow area, and a ratio of the total hollow area to the block area ranged between 0.1 and 0.5.

### BACKGROUND OF THE INVENTION

### Field of the Invention

The present invention relates to a pad structure.

### Description of the Related Art

In the process for conventional CUP (Circuit Under Pad) structure, force applied by wire bonding for packing and/or wafer probing for electrical test to the CUP structure easily causes cracks in dielectric layer between two conductive layers of the CUP structure or in inter-metal dielectric (IMD) layer of one conductive layer. Therefore, how to propose a new CUP structure to improve the aforementioned problems is one of the efforts of the technical practitioners.

### SUMMARY OF THE INVENTION

The present invention provides a pad structure capable of improving the conventional problem.

An embodiment of the present invention discloses a pad structure. The pad structure includes a conductive layer, a pad layer, a protective layer and a dielectric layer. The conductive layer is a portion of a circuit. The protective layer covers the pad layer and has an opening for exposing a portion of the pad layer. The dielectric layer is formed between the conductive layer and the pas layer for completely separating the conductive layer and the pad layer in region of the opening. The conductive layer includes a number of effective blocks, and a proportion of a block area of a block of the effective blocks to a total block area of the effective blocks ranges between 40%-50%. The first block has a hollow portion, the hollow portion has a hollow area, and a ratio of the hollow area to the block area ranges between 0.1 and 0.5.

An another embodiment of the present invention discloses a pad structure. The pad structure includes a conductive layer, a pad layer, a protective layer and a dielectric layer. The conductive layer is a portion of a circuit. The protective layer covers the pad layer and has an opening for exposing a portion of the pad layer. The dielectric layer is formed between the conductive layer and the pas layer for completely separating the conductive layer and the pad layer in region of the opening. The conductive layer includes a first block and a second block, the first block and the second block respectively has a first width and a second width, there is a first interval between the first block and the second block, the first width, the second width and the first interval are sizes along the same direction, each of the first width and the second width is greater than a threshold width, and the first interval is greater than a threshold interval.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1A shows a diagram of a pad structure.

FIG. 1B shows a top view of a conductive layer of the pad structure according to an embodiment of the present invention.

FIGS. 2A to 2H show diagrams of the hollow portion in others embodiments of the present invention.

FIGS. 3A to 3B show diagrams of the conductive layer in others embodiments of the present invention.

FIGS. 4A-4B shows a design process diagram of the conductive layer of the pad structure of FIG. 1B.

### DETAILED DESCRIPTION OF THE INVENTION

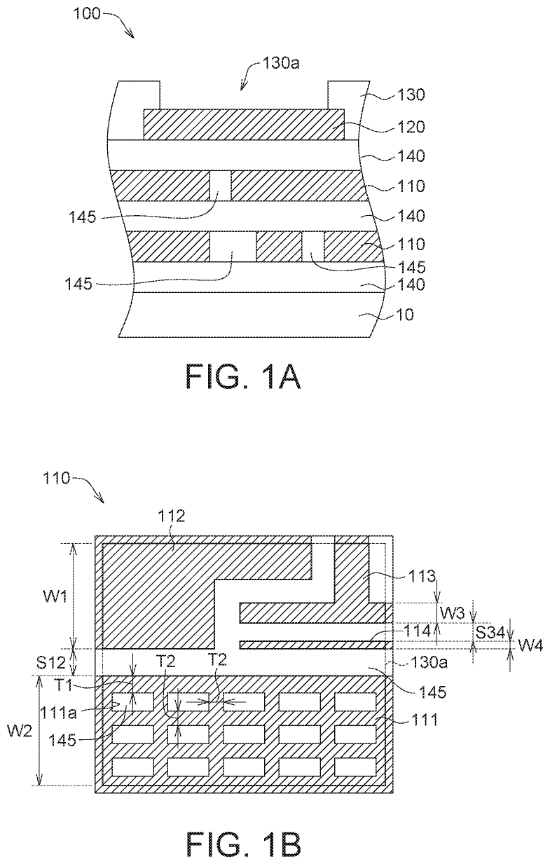

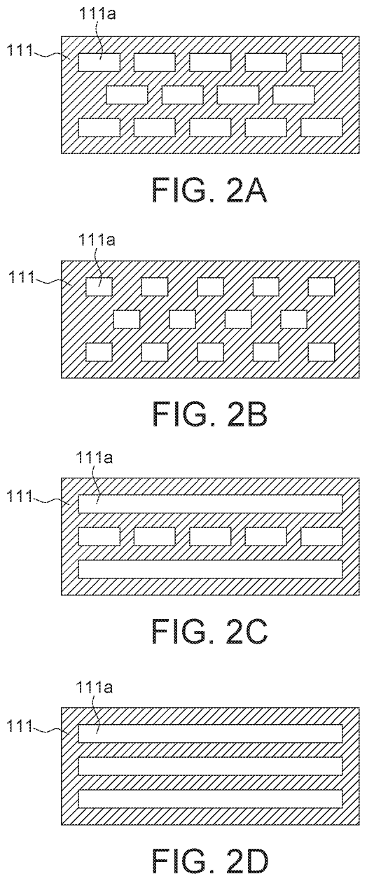

Referring to FIGS. 1A and 1B, FIG. 1A shows a diagram of a pad structure 100, and FIG. 1B shows a top view of a conductive layer 110 of the pad structure 100 according to an embodiment of the present invention.

As shown in FIG. 1A, the pad structure 100 may be formed on a substrate 10, such as a circuit board or a wafer. In one embodiment, at least one of the pad structures 100 and the substrate 10 are, for example, at least a portion of a chip, wherein the chip is, for example, a central processing unit (CPU).

As shown in FIG. 1A, the pad structure 100 includes a plurality of conductive layers 110, a pad layer 120, a protective layer 130 and a plurality of dielectric layers 140. The protective layer 130 covers the pad layer 120 and has an opening 130a to expose a portion of the pad layer 120, so that a bonding wire (not shown) is formed on the pad layer 120 through the opening 130a. At least one of the dielectric layers 140 is formed between the conductive layers 110 for separating the conductive layers 110. One of the dielectric layers 140 is formed between the conductive layer 110 and the substrate 10 for separating the conductive layer 110 and the substrate 10. One of the dielectric layers 140 is formed between the conductive layer 110 and the pad layer 120 for separating the conductive layers 110 and the pad layer 120.

The conductive layer 110 is formed above or on the substrate 10 with the dielectric layer 140 in between. In the present embodiment, the pad structure 100 is, for example, a CUP structure, and thus the conductive layers 110 are a portion of a circuit of the chip. As shown in FIG. 1A, in region of the opening 130a, the conductive layers 110 are separated from each other. Outside the region of the opening 130a, two conductive layers 110 could be electrically connected through a conductive via (not illustrated) penetrating the dielectric layer 140. Similarly, in region of the opening 130a, the pad layer 120 and the conductive layer 110 are separated from each other. Outside the region of the opening 130a, the pad layer 120 and the conductive layer 110 could be electrically connected through a conductive via (not illustrated) penetrating the dielectric layer 140.

As shown in FIG. 1B, the conductive layer 110 includes a plurality of blocks (such as the thick line area shown in FIG. 1B), such as the first block 111, the second block 112, the third block 113, and the fourth block 114. The first block 111, the second block 112, the third block 113, and the fourth block 114 are separated from each other, and each block is a continuous (or enclosed) extended block. The opening 130a is projected onto the conductive layer 110 to form a projection area (for example, the virtual frame shown in FIG. 1B), and the first block 111, the second block 112, the third block 113, and the fourth block 114 are located within the projection area. In addition, the present embodiment of the invention do not limit the number of blocks, and the number of blocks may be less than four or more than four.

As shown in FIG. 1B, in these blocks, the block having a block area larger than a threshold value may have at least one hollow portion 111a. For example, the block area of the first block 111 is larger than the threshold value, and thus the first block 111 may have at least one hollow portion 111a. The block area herein refers to the top-viewed area shown in FIG. 1B, that is, the area surrounded (the portion beyond the opening 130a is defined by the boundary of the opening 130a) by outer boundary of the first block 111. Each hollow portion 111a may be filled with dielectric material 145. In addition, the dielectric material 145 may also be filled the space between any two blocks. The dielectric material 145 is an inter-metal dielectric (IMD). Compared with the block without any hollow portion 111a, the first block 111 having the hollow portion 111a can increase the stiffness of the conductive layer 110, and avoid the deformation of the conductive layer 110 caused by the force applied during the wire bonding process and avoid cracks in in dielectric layer 140 above and below the conductive layer 110 and the dielectric material 145.

The aforementioned threshold value may be a predetermined proportion of an area to the total block area A1 of a number of effective blocks, wherein the predetermined proportion ranges between 40% and 50%. Furthermore, in these blocks, each of the block area of the first block 111, the block area of the second block 112 and the block area of the third block 113 is larger than an effective block area, and thus the first block 111, the second block 112 and the third block 113 are defined as the effective blocks. The effective block refers to the block that is eligible to be included in the calculation of the total block area A1. The total block area A1 is the sum of the block area of the first block 111, the block area of the second block 112 and the block area of the third block 113. Due to the block area of the fourth block 114 is smaller than the effective block area, the calculation of the total block area A1 does not include the block areas of the fourth block 114. In an embodiment, the effective block area is, for example, 10% of the area of enclosed by opening 130a.

The effective block having the block area ranging between 40% to 50% of the total block area A1 is required to form the hollow portion 111a. In the present embodiment, only the block area of the first block 111 in the effective blocks ranges between 40% to 50% of the total block area A1, and thus the hollow portion 111a only formed on the first block 111. In another embodiment, the threshold value may be higher than 50% or lower than 40%. The lower the threshold value, the more the conductive layer 110 is hollowed out, and thus it causes the resistance of the conductive layer 110 to increase. The higher the threshold value is, the less the conductive layer 110 is hollowed out, and it is not significant for improving the rigidity of the conductive layer 110. Since the threshold value of the present embodiment of the invention is between 40% and 50%, the dual effects of the excellent conductivity and rigidity of the conductive layer 110 could be achieved.

The area sum of all the hollow portions 111a of the first block 111 is the total hollow area A2. In an embodiment, the ratio (A2/A3) of the total hollow area A2 of the first block 111 to the block area A3 of the first block 111 ranges between 0.1 and 0.5. As a result, the conductive layer 110 has sufficient stiffness to resist the applied force in the wire bonding process to avoid crack in dielectric layer 140 above and below the conductive layer 110 and the dielectric material 145 between the blocks 111 and 112, for example. The aforementioned block area A3 is, for example, an area surrounded by the outer boundary of the first block 111.

As shown in FIG. 1B, a shape of the hollow portion 111a is, for example, a rectangle, and the minimum distance T1 between the hollow portion 111a and the outer boundary of the first block 111 ranges, for example, 5 μm and 10 μm. The minimum distance T2 of adjacent two hollow portions 111a ranges, for example, 5 μm and 10 μm.

As shown in FIG. 1B, the first block 111 and the second block 112 have a first width W1 and a second width W2, respectively, and the first block 111 has a first interval S12 between the second block 112 and the second block 112, the first width W1, the second width W2, and the first interval S12 are sizes along the same direction. Each of the first width W1 and the second width W2 is greater than a threshold width, and the first interval S12 is greater than the threshold interval. As a result, the conductive layer 110 can provide sufficient stiffness to resist the applied force in the wire bonding process to prevent the dielectric material 145 from being cracked due to deformation of the conductive layer 110. In an embodiment, the aforementioned threshold width is, for example, equal to or larger than 10 m and the aforementioned threshold interval is, for example, equal to or larger than 2 μm (minimum 2 μm).

In addition, if the width is smaller than the threshold width, the interval between two blocks may not be considered. For example, as shown in FIG. 1B, the third block 113 and the fourth block 114 respectively have a third width W3 and a fourth width W4, and there is a second interval S34 between the third block 113 and the fourth block 114. Each of the third width W3 and the fourth width W4 is smaller than the threshold width, it indicates that the block has a certain stiffness (the larger the width, the larger the block area, the lower the block stiffness), so the second interval S34 may be disregarded, for example, the second interval. S34 may be less than the threshold interval.

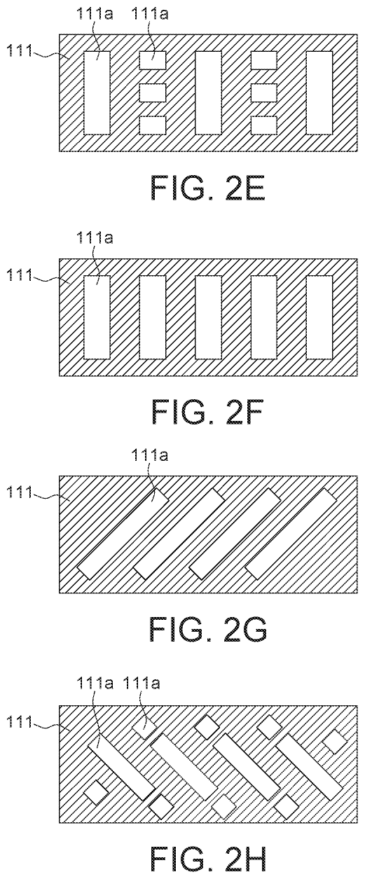

FIGS. 2A to 2H show diagrams of the hollow portion 111a in others embodiments of the present invention. It can be seen from these figures that in one block, the shape of one of the hollow portions 111a may be a polygon, such as a square, a rectangle, a strip, a trapezoid, etc., or is a circle or an ellipse. Furthermore, the shape of two of the hollow portions 111a may be the same or different. A number of the hollow portions 111a may be arranged in parallel with each other. The hollow portion 111a may be disposed obliquely or in parallel with respect to the edge of the block.

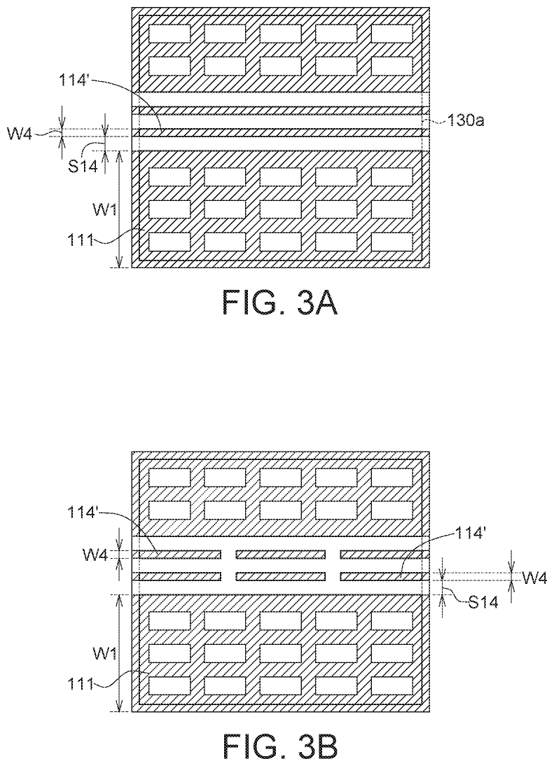

FIGS. 3A to 3B show diagrams of the conductive layer 110 in others embodiments of the present invention. As can be seen from these figures, the width W4′ of the block 114′ is less than the threshold width, and thus the interval S14 between the adjacent blocks 114′ and the first block 111 can be less than the threshold interval.

Although the foregoing embodiment is described by taking one of the conductive layers 110 as an example, however, such exemplification is not meant to be for limiting. Any of the foregoing conductive layers 110 may have the foregoing structure, and details are not described herein again.

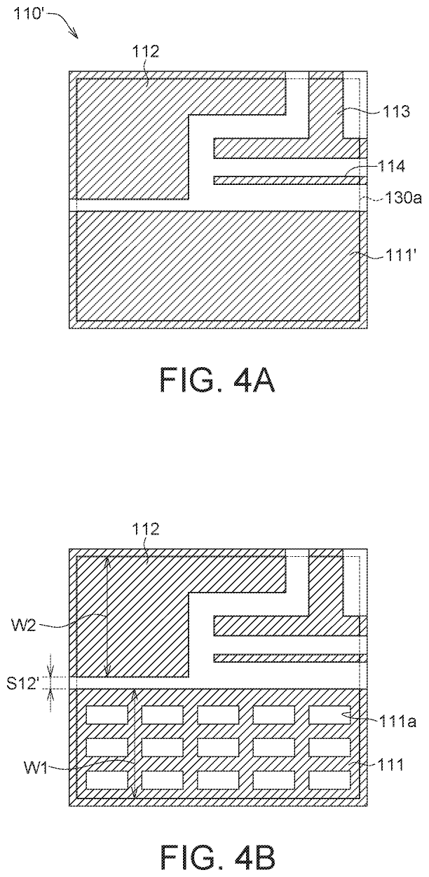

Referring to FIGS. 4A-4B a design process diagram of the conductive layer 110 of the pad structure 100 of FIG. 1B is shown. The design process of each conductive layer 110 of the pad structure 100 is the same as the following process.

Firstly, as shown in FIG. 4A, a pattern of the initially design conductive layer 110′ is provided. The pattern of the conductive layer 110′ may be determined according to the circuit function of the pad structure 110 and/or the substrate 10, which is not limited by the embodiment of the present invention.

Then, the region of the opening 130a is defined.

Then, a plurality of blocks of the conductive layer 110′ are determined, each block being a continuous (enclosed) extended block, and any two blocks are separated from each other. According to this principle, the first block 111′, the second block 112, the third block 113, and the fourth block 114 are determined in the conductive layer 110′. Next, the block area of each block is calculated. For example, the block area of the first block 111′, the block area of the second block 112, the block area of the third block 113, and the block area of the fourth block 114 are calculated to be obtained. Then, the block whose block area is smaller than the effective block area is excluded. In this example, the block area of the fourth block 114 is smaller than the effective block area, and thus the fourth block 114 is not considered in the subsequent design process.

Then, in these blocks, the block whose block area is larger than the threshold value is selected. For example, the total block area of the first block 111′, the second block 112, and the third block 113 is A1, and the threshold value is between, for example, 40% to 50%. In the first block 111′, the second block 112, and the third block 113, only the block area of the first block 111′ is between 40% to 50% of the total block area A1, and thus the first block 111 is selected to be hollowed.

Then, as shown in FIG. 4B, at least one hollow portion 111a is formed in the first block 111′ to form the first block 111. In the actual semiconductor process, the hollow portion 111a is filled with dielectric material 145. Due to the first block 111 has the hollow portion 111a filled with the dielectric material 145, the stiffness of the first block 111 can be increased.

Then, the stiffness of the conductive layer 110 can be enhanced by increasing the interval of two blocks, such that the dielectric layer 140 (shown in the pad structure 100 of FIG. 1A) between the two conductive layers 110 is prevented from being cracked during the wire bonding process. For example, in any two adjacent blocks, it is determined whether the width of each block is greater than the threshold width, wherein the direction of each width is along the same direction. If so, whether the interval between the two blocks is smaller than the threshold interval is determined. If the interval between the two blocks is less than the threshold interval, then the interval between the two blocks may be increased to be substantially equal to or greater than the threshold interval.

Furthermore, as shown in FIG. 4B, the first width W1 of the first block 111 and the second width W2 of the second block 112 are greater than the threshold width, and the interval S12′ between the first block 111 and the second block 112 is less than the threshold interval, and thus the interval S12′ may be increased to be substantially equal to the interval S12 of FIG. 1B, wherein the interval S12 is substantially equal to or greater than the threshold interval.

In another embodiment, if the interval between the first block 111 and the second block 112 is greater than the threshold interval, a block whose width is less than the threshold may be added between the first block 111 and the second block 112. The block is, for example, the fourth block 114′ shown in FIG. 3A.

While the invention has been described by way of example and in terms of the preferred embodiment (s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A pad structure formed on a substrate and comprising:
a conductive layer being a portion of a circuit;
a pad layer;
a protective layer covering the pad layer and having an opening for exposing a portion of the pad layer; and
a dielectric layer formed between the pad layer and the conductive layer for completely separating the pad layer and the conductive layer in region of the opening;
wherein the conductive layer comprises a plurality of effective blocks, and a proportion of a block area of a first block of the effective blocks to a total block area of the effective blocks ranges between 40%-50%, the first block has a hollow portion, the hollow portion has a hollow area, and a ratio of the hollow area to the block area ranges between 0.1 and 0.5.

2. A pad structure formed on a substrate and comprising:
a conductive layer being a portion of a circuit;
a pad layer;
a protective layer covering the pad layer and having an opening for exposing a portion of the pad layer; and
a dielectric layer formed between the pad layer and the conductive layer for completely separating the pad layer and the conductive layer in region of the opening;
wherein the conductive layer comprises a first block and a second block, the first block and the second block respectively has a first width and a second width, there is a first interval between the first block and the second block, the first width, the second width and the first interval are sizes along the same direction, each of the first width and the second width is greater than a threshold width, and the first interval is greater than a threshold interval.

3. The pad structure according to claim 1, wherein the opening is projected onto the conductive layer to form a projecting area, and the first block is located within the projecting area.

4. The pad structure according to claim 2, wherein the opening is projected onto the conductive layer to form a projecting area, and the first block is located within the projecting area.

5. The pad structure according to claim 1, wherein the block area is the area surrounded by outer boundary of the first block.

6. The pad structure according to claim 2, wherein the block area is the area surrounded by outer boundary of the first block.

7. The pad structure according to claim 1, wherein area of each effective block is larger than 10% of an opening area of the opening.

8. The pad structure according to claim 1, wherein a minimum distance between the hollow portion and an outer boundary of the first block ranges between 5 μm and 10 μm.

9. The pad structure according to claim 1, wherein the first block comprises a plurality of the hollow portions, and a minimum distance of adjacent two hollow portions ranges between 5 μm and 10 μm.

10. The pad structure according to claim 1, wherein the first block includes a plurality of the hollow portions, the hollow portions are parallel to each other.

11. The pad structure according to claim 1, wherein the hollow portions is inclined with respect to an edge of the first block.

12. The pad structure according to claim 1, wherein a shape of the hollow portion is polygonal, circular or elliptical.

13. The pad structure according to claim 2, wherein the opening is projected onto the conductive layer to form a projecting area, and the first block and the second block are located within the projecting area.

14. The pad structure according to claim 2, wherein the conductive layer further comprises a third block and a fourth block, the third block and the fourth block respectively have a third width and a fourth width, there is a second interval between the third block and the fourth block, each the third width and the fourth width is smaller than the threshold width, and the second interval is smaller than the threshold interval.
